(19) United States
(12) Patent Application Publication
(10) Pub. No.: US 2009/0218600 A1
(43) Pub. Date: Sep. 3, 2009

(54) Memory Cell Layout

(76) Inventors: Human Park, Tuscon, AZ (US); Ulrich Klostermann, Munich (DE)

Correspondence Address: SLATER & MATSIL, L.L.P., 17950 PRESTON ROAD, SUITE 1000, DALLAS, TX, 75252, US

(21) Appl. No.: 12/040,227

(22) Filed: Feb. 29, 2008

(51) Int. Cl. H01L 29/76; H01L 21/82; G06F 17/50

(52) U.S. Cl. 257/202; 438/128; 716/8; 257/E29.226; 257/E21.602

(57) ABSTRACT

A method for manufacturing an integrated circuit and an integrated circuit are described. In one embodiment, the method for manufacturing the integrated circuit includes determining a layout for numerous memory elements based on memory-specific parameters, and determining a layout for a front-end-of-line (FEOL) component of the integrated circuit based on electrical parameters. Once these two layouts are determined, the layouts are combined to produce a layout for a memory cell on the integrated circuit.

### BACKGROUND

Memory devices are used in essentially all computing applications and in many electronic devices. For some applications, non-volatile memory, which retains its stored data even when power is not present, may be used. For example, non-volatile memory is typically used in digital cameras, portable audio players, wireless communication devices, personal digital assistants, and peripheral devices, as well as for storing firmware in computers and other devices.

A variety of memory technologies have been developed. Non-volatile memory technologies include flash memory, magnetoresistive random access memory (MRAM), phase change random access memory (PCRAM), and conductive bridging random access memory (CBRAM). Due to the great demand for memory devices, researchers are continually improving memory technology and developing new types of memory, including new types of non-volatile memory.

The scale of electronic devices is constantly being reduced. For memory devices, conventional technologies, such as flash memory and DRAM, which store information based on storage of electric charges, may reach their scaling limits in the foreseeable future. Additional characteristics of these technologies, such as the high switching voltages and limited number of read and write cycles of flash memory, or the limited duration of the storage of the charge state in DRAM, pose additional challenges. To address some of these issues, researchers are investigating memory technologies that do not use storage of an electrical charge to store information. One such technology is resistivity changing memory, which stores information based on changes in the resistivity of a memory element. Depending on the resistivity changing memory technology being used, the resistivity of the storage layer is typically switched between a low resistivity state and a high resistivity state through the application of voltage or current across the storage layer.

One type of resistivity changing memory is magnetoresistive random access memory (MRAM). FIG. 1 shows a perspective view of an MRAM array 100 having bit lines 102 disposed in an orthogonal direction to word lines 104 in adjacent metallization layers. Magnetoresistive memory elements 106 are electrically coupled to the bit lines 102 and word lines 104, and are positioned between the bit lines 102 and word lines 104 at locations where a bit line 102 crosses a word line 104. The magnetoresistive memory elements 106 may include a free layer 108, a tunnel layer 110, and a fixed layer 112. The free layer 108 and fixed layer 112 may each include a plurality of magnetic metal layers (not shown). These magnetic metal layers may, for example, include eight to twelve layers of materials such as PtMn, CoFe, Ru, and NiFe. The tunnel layer 110 may include a dielectric, such as Al₂O₃.

The fixed layer 112 may be magnetized in a fixed direction, while the direction of magnetization of the free layer 108 may be switched, changing the resistance of the magnetoresistive memory element 106. One bit of digital information may be stored in a magnetoresistive memory element 106 by running a current in the appropriate direction through the bit line 102 and the word line 104 that intersect at the selected magnetoresistive memory element 106, creating a sufficient magnetic field to set the direction of magnetization of the free layer 108. Information may be read from a magnetoresistive memory element 106 by applying a voltage across the memory element, and measuring the resistance. For example, if the direction of magnetization of the free layer 108 is parallel to the direction of magnetization of the fixed layer 112, then the measured resistance may be low, representing a value of “0” for the bit. If the direction of magnetization of the free layer 108 is anti-parallel to the direction of magnetization of the fixed layer 112, then the resistance may be high, representing a value of “1”.

It will be understood that the view shown in FIG. 1 is simplified, and that actual MRAM cells may include additional components. For example, in some MRAM designs, known as thermal select MRAM devices, switching of the free layer is facilitated by using a heating current to heat the free layer to a temperature that permits its direction of magnetization to be more easily switched. This can be used, for example, to prevent inadvertent switching of nearby cells in a densely-packed MRAM array. As will be discussed below, such thermal select MRAM cells may include a transistor, as well as a magnetoresistive memory element. The transistor may be used to select the cell, and to drive the current that is used for heating the cell. For example, a word line may be used to select a cell by being electrically connected to the gate of the transistor, so that a heating current flows through the cell from the bit line when the transistor is selected. Such a select transistor may also be used in spin-injection MRAM memory cells, which use bipolar switching current through a magnetic tunnel junction (MTJ) to select and switch the magnetization direction to the parallel or antiparallel state, or other types of MRAM cells. Additionally, the transistor may be used for selecting the read current path to read out the cell resistance. Other variations, that include a variety of components in the design of a memory cell also, are possible.

It will further be recognized that the view shown in FIG. 1 represents only a small portion of an actual MRAM device. Depending on the organization and memory capacity of the device, there may be hundreds or thousands of bit lines and word lines in a memory array. For example, a 1 Mb MRAM device (i.e., an MRAM device storing approximately one million bits of data) may include two arrays, each of which has 1024 word lines and 512 bit lines. Additionally, in some MRAM devices, there may be multiple layers of memory elements, which may share bit lines and/or word lines.

Another type of resistivity changing memory is known as phase change random access memory (PCRAM). The resistivity changing memory elements used in PCRAM are phase changing memory elements that include a phase changing material. The phase changing material can be switched between at least two different crystallization states (i.e. the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states also may be used.

Phase changing memory elements may change from the amorphous state to the crystalline state (and vice versa) due to temperature changes of the phase changing material. These temperature changes may be caused by using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory element, a sensing current may be routed through the phase changing material (or a sensing voltage may be applied across the phase changing material), thereby sensing the resistivity of the resistivity changing memory element, which represents the memory state of the memory element.

FIG. 2 illustrates a cross-sectional view of an exemplary phase changing memory element 200 (active-in-via type). The phase changing memory element 200 includes a first electrode 202, a phase changing material 204, a second electrode 206, and an insulating material 208. The phase changing material 204 is laterally enclosed by the insulating material 208. To use the phase changing memory element in a memory cell, a selection device (not shown), such as a transistor, a diode, or another active device, may be coupled to the first electrode 202 or to the second electrode 206 to control the application of a current or a voltage to the phase changing material 204 via the first electrode 202 and/or the second electrode 206. To set the phase changing material 204 to the crystalline state, a current pulse and/or voltage pulse may be applied to the phase changing material 204, wherein the pulse parameters are chosen such that the phase changing material 204 is heated above its crystallization temperature, while keeping the temperature below the melting temperature of the phase changing material 204. To set the phase changing material 204 to the amorphous state, a current pulse and/or voltage pulse may be applied to the phase changing material 204, wherein the pulse parameters are chosen such that the phase changing material 204 is quickly heated above its melting temperature, and is quickly cooled.

The phase changing material 204 may include a variety of materials. The phase changing material 204 may include or consist of a chalcogenide alloy that includes one or more elements from group VI of the periodic table. Alternatively, the phase changing material 204 may include or consist of a chalcogenide compound material, such as GeSbTe, SbTe, GeTe or AgInSbTe. In some devices, the phase changing material 204 may include or consist of chalcogen free material, such as GeSb, GaSb, InSb, or GeGaInSb. Generally, the phase changing material 204 may include or consist of any suitable material including one or more of the elements Ge, Sb, Te, Ga, Bi, Pb, Sn, Si, P, O, As, In, Se, and S.

At least one of the first electrode 202 and the second electrode 206 may include or consist of Ti, V, Cr, Zr, Nb, Mo, Hf, Ta, W, or mixtures or alloys thereof. Alternatively, at least one of the first electrode 202 and the second electrode 206 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

FIG. 3 illustrates a block diagram of a memory device 300 including a write pulse generator 302, a distribution circuit 304, phase changing memory elements 306a-306d (for example phase changing memory elements 200 as shown in FIG. 2), and a sense amplifier 308. The write pulse generator 302 generates current pulses or voltage pulses that are supplied to the phase changing memory elements 306a-306d via the distribution circuit 304, thereby programming the memory states of the phase changing memory elements 306a-306d. The distribution circuit 304 includes a plurality of transistors that supply direct current pulses or direct voltage pulses to the phase changing memory elements 306a-306d or to heaters (not shown) disposed adjacent to the phase changing memory elements 306a-306d.

As already indicated, the phase changing material of the phase changing memory elements 306a-306d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 308 is capable of determining the memory state of one of the phase changing memory elements 306a-306d in dependence on the resistance of the phase changing material.

To achieve high memory densities, the phase changing memory elements 306a-306d may be capable of storing multiple bits of data, i.e., the phase changing material may be programmed to more than two resistance values. For example, if a phase changing memory elements 306a-306d is programmed to one of three possible resistance levels, 1.5 bits of data per memory element can be stored. If the phase changing memory element is programmed to one of four possible resistance levels, two bits of data per memory element can be stored, and so on.

The embodiment shown in FIG. 3 may also be applied in a similar manner to other types of resistivity changing memory elements like programmable metallization cells (PMCs), magnetoresistive memory elements (e.g., MRAMs) or organic memory elements (e.g., ORAMs).

Another type of resistivity changing memory element may be formed using carbon as a resistivity changing material. Generally, amorphous carbon that is rich is sp3-hybridized carbon (i.e., tetrahedrally bonded carbon) has a high resistivity, while amorphous carbon that is rich in sp2-hybridized carbon (i.e., trigonally bonded carbon) has a low resistivity. This difference in resistivity can be used in a resistivity changing memory cell.

In one embodiment, a carbon memory element may be formed in a manner similar to that described above with reference to phase changing memory elements. A temperature-induced change between a sp3-rich state and a sp2-rich state may be used to change the resistivity of an amorphous carbon material. These differing resistivities may be used to represent different memory states. For example, a high resistance sp3-rich state can be used to represent a “0”, and a low resistance sp2-rich state can be used to represent a “1”. It will be understood that intermediate resistance states may be used to represent multiple bits, as discussed above.

Generally, in this type of carbon memory element, application of a first temperature causes a change of high resistivity sp3-rich amorphous carbon to relatively low resistivity sp2-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

Another way in which resistivity changes in amorphous carbon can be used to store information is by field-strength induced growth of a conductive path in an insulating amorphous carbon film. For example, applying voltage or current pulses may cause the formation of a conductive sp2 filament in insulating sp3-rich amorphous carbon. The operation of this type of resistive carbon memory is illustrated in FIGS. 4A and 4B.

FIG. 4A shows a carbon memory element 400 that includes a top contact 402, a carbon storage layer 404 including an insulating amorphous carbon material rich in sp3-hybridized carbon atoms, and a bottom contact 406. As shown in FIG. 4B, by forcing a current (or voltage) through the carbon storage layer 404, a sp2 filament 450 can be formed in the sp3-rich carbon storage layer 404, changing the resistivity of the memory element. Application of a current (or voltage) pulse with higher energy (or, in some devices, reversed polarity) may destroy the sp2 filament 450, increasing the resistance of the carbon storage layer 404. As discussed above, these changes in the resistance of the carbon storage layer 404 can be used to store information, with, for example, a high resistance state representing a “0” and a low resistance state representing a “1”. Additionally, intermediate degrees of filament formation or formation of multiple filaments in the sp3-rich carbon film may be used to provide multiple varying resistivity levels, which may be used to represent multiple bits of information in a carbon memory element. In some devices, alternating layers of sp3-rich carbon and sp2-rich carbon may be used to enhance the formation of conductive filaments through the sp3-rich layers, reducing the current and/or voltage that may be used to write a value to this type of carbon memory. Similar methods of forming a conductive path through an insulating material are used, for example, in conductive bridging (CBRAM) memory devices and in transition metal oxide (TMO) memory devices.

Resistivity changing memory elements, such as the phase changing memory elements, carbon memory elements, magnetoresistive memory elements, and other resistivity changing memory elements discussed above may be used as part of a memory cell, along with a transistor, diode, or other active component for selecting the memory cell. FIG. 5A shows a schematic representation of such a memory cell that uses a resistivity changing memory element. The memory cell 500 includes a select transistor 502 and a resistivity changing memory element 504. The select transistor 502 includes a source 506 that is connected to a bit line 508, a drain 510 that is connected to the memory element 504, and a gate 512 that is connected to a word line 514. The resistivity changing memory element 504 also is connected to a common line 516, which may be connected to ground, or to other circuitry, such as circuitry (not shown) for determining the resistance of the memory cell 500, for use in reading. Alternatively, in some configurations, circuitry (not shown) for determining the state of the memory cell 500 during reading may be connected to the bit line 508. It should be noted that as used herein the terms connected and coupled are intended to include both direct and indirect connection and coupling, respectively.

To write to the memory cell 500, the word line 514 is used to select the memory cell 500, and a current (or voltage) pulse on the bit line 508 is applied to the resistivity changing memory element 504, changing the resistance of the resistivity changing memory element 504. Similarly, when reading the memory cell 500, the word line 514 is used to select the cell 500, and the bit line 508 is used to apply a reading voltage (or current) across the resistivity changing memory element 504 to determine the resistance of the resistivity changing memory element 504.

The memory cell 500 may be referred to as a 1T1J cell, because it uses one transistor, and one memory “junction” (the resistivity changing memory element 504). Typically, a memory device will include an array of many such cells. It will be understood that other configurations for a 1T1J memory cell, or configurations other than a 1T1J configuration may be used with a resistivity changing memory element. For example, in FIG. 5B, an alternative arrangement for a 1T1J memory cell 550 is shown, in which a select transistor 552 and a resistivity changing memory element 554 have been repositioned with respect to the configuration shown in FIG. 5A. In this alternative configuration, the resistivity changing memory element 554 is connected to a bit line 558, and to a source 556 of the select transistor 552. A drain 560 of the select transistor 552 is connected to a common line 566, which may be connected to ground, or to other circuitry (not shown), as discussed above. A gate 562 of the select transistor 552 is controlled by a word line 564. It will further be understood that although transistors will be described as having particular “source” and “drain” regions, the source and drain regions may be reversed (i.e., “source” regions being replaced with “drain” regions and “drain” regions being replaced with “source” regions) without substantially altering the principles of the various embodiments of the invention.

Many of the resistivity changing memory technologies described above and other advanced memory technologies use relatively high write currents compared to DRAM and other conventional memory technologies. Such high write currents may be used, for example, to heat the phase change material in PCRAM devices, to heat the magnetoresistive memory element in thermal select MRAM devices, or to generate a field sufficient to form a conductive path in a carbon memory device or CBRAM memory device. Such high write currents may have an effect on memory cell size, due to contacts and the amount of current that can be driven by a transistor. Because the amount of current that can be driven is limited by the transistor dimensions, to drive a large write current for a resistivity changing memory device, a relatively large transistor is typically needed.

Generally, as the size of memory cells becomes smaller, the density of cells in a memory device increases. To be competitive with more conventional memories, such as DRAM, it may be desirable to achieve a cell size of less than 10F2, where F is the minimum feature size. For technology below a 90 nm node size, it may be challenging to achieve a cell size of less than 10F2, while using a transistor or other select device that is able to drive the write current used by a resistivity changing memory element or other advanced memory element.

Some memory technologies may present additional challenges in achieving a small cell size, due to limits related to the memory technology. For example, if MRAM cells are spaced too closely, there is a possibility of magnetic interference between cells. Similarly, for PCRAM devices, thermal select MRAM devices, and other memory devices that rely on heating, there may be interference between cells if the cells are spaced too closely. For other memory types, such as CBRAM or carbon memories, there may be electrical cell-to-cell crosstalk, or interference based on field strength during writing.

Additionally, memory cells for some types of memory may have characteristics that make them more difficult to arrange within small cells. For example, in many MRAM devices, the magnetic tunnel junction (MTJ—i.e., the memory element of an MRAM device) has an elliptical shape. Arranging such elliptical MTJs so that they do not interfere with each other can present layout challenges.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a portion of a conventional magnetoresistive memory (MRAM) device;

FIG. 2 show a conventional phase changing (PCRAM) memory element;

FIG. 3 shows a block diagram of a memory device using resistivity changing memory elements;

FIGS. 4A and 4B illustrate the operation of a carbon memory cell;

FIGS. 5A and 5B show schematic representations of a memory cell including a resistivity changing memory element and a select transistor;

FIG. 6 illustrates a memory cell layout method according to an embodiment of the invention;

FIG. 7 is a block diagram of a method for MRAM cell layout in accordance with an embodiment of the invention;

FIG. 8 is a block diagram of a general method for memory cell layout according to an embodiment of the invention;

FIG. 9 shows an example process for determining a layout for a memory cell with a 65 nm feature size in accordance with an embodiment of the invention;

FIG. 10 illustrates an example process for determining a layout for a memory cell with a 32 nm feature size in accordance with an embodiment of the invention;

FIG. 11 shows an example layout of an integrated circuit including memory elements arranged at an angle, in accordance with an embodiment of the invention;

FIG. 12 shows an example layout of an integrated circuit including memory elements arranged at a first and a second angle to form a criss-cross pattern, in accordance with an embodiment of the invention;

FIG. 13 is a block diagram of a computer system that may be used to perform layout methods in accordance with an embodiment of the invention; and

FIGS. 14A and 14B show a memory module that may include an integrated circuit memory device according to an embodiment of the invention.

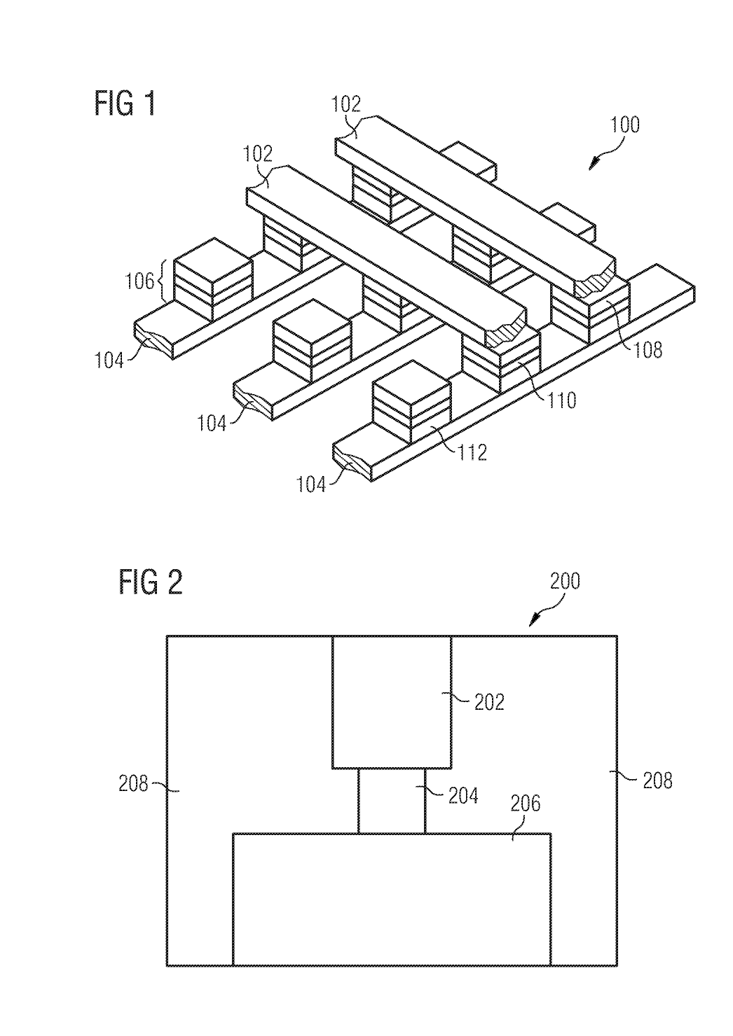

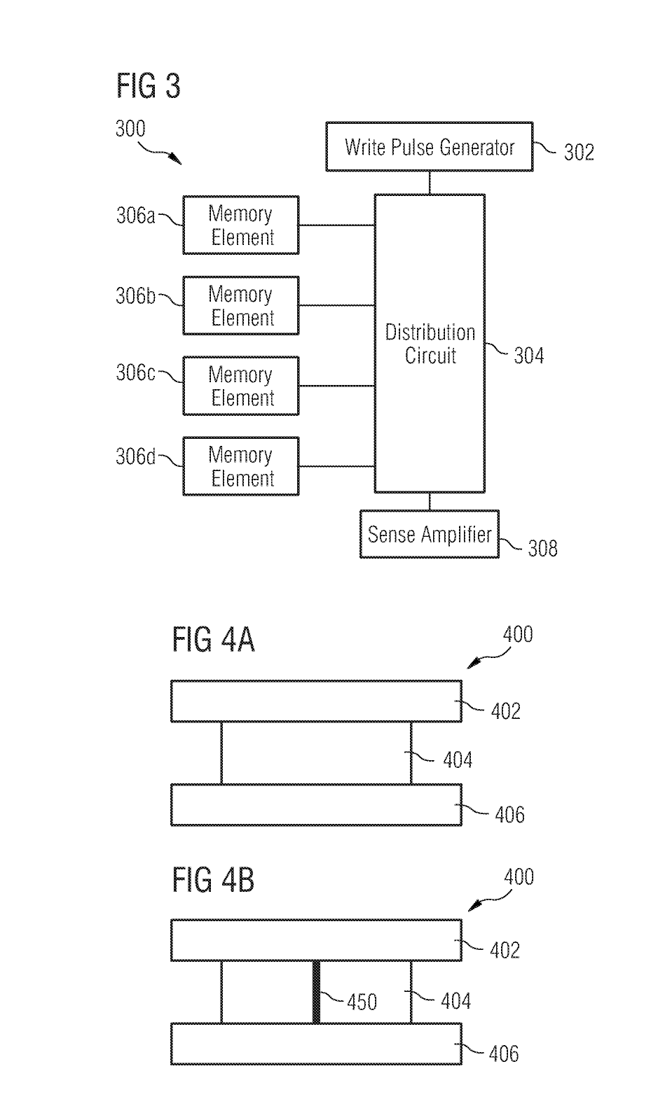

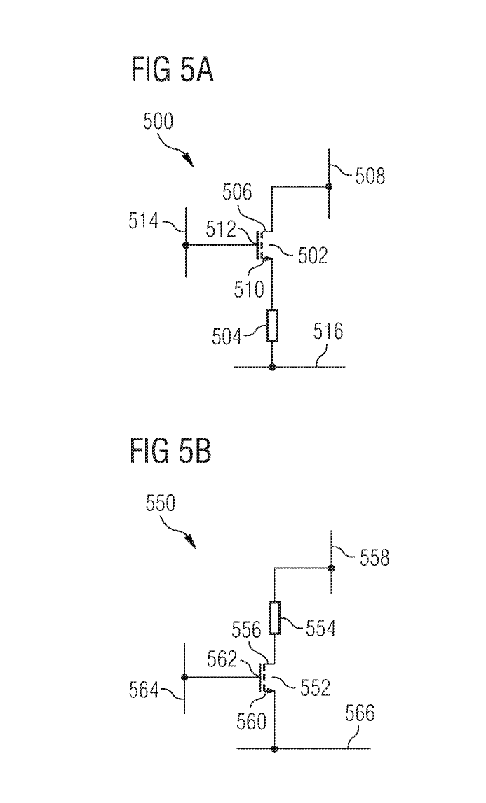

### DETAILED DESCRIPTION OF ILLUSTRATIVE EMBODIMENTS

While the memory device described below will be discussed with reference to an MRAM device, it will be understood that the apparatus and methods described herein could be used with other memory devices, including other types of resistivity changing memory elements such as those discussed above, including PCRAM, carbon memory, various types of MRAM (e.g., spin injection MRAM), and CBRAM memory elements, as well as with other advanced memory elements. Additionally, a memory cell will often be described below as using a select transistor. It will be understood that other select devices, such as a diode, may be used instead of a transistor, and that many different types of diodes or transistors (e.g., vertical FETs, FinFETs, etc.) may be used as a select device.

In accordance with an embodiment of the invention, a sub-10F² cell structure can be achieved in a cell layout by tilting and shifting the positions of memory elements in the layout. In accordance with an embodiment of the invention, a method of layout design may include a systematic algorithm for optimization of advanced memory element configuration. In some embodiments, cell layout issues may be addressed using a layout method that decouples electrical parameters of the cell, such as the write current and memory element resistance, from memory-specific parameters of the cell. For an MRAM device, for example, these memory-specific parameters may include the minimum distance between cells to avoid interference, the size of the MTJ, and the aspect ratio of the MTJ. The angles and distances between cells can then be determined based on a combination of the electrical parameters and the memory-specific parameters.

Additionally, since many memory technologies may use a select device, such as a diode or transistor, the geometrical size of the select device may be taken into account when assessing the overall cell size of a particular memory technology. For example, a relatively high select current range, ranging, for example, from approximately 30 to approximately 300 μA may be used to select an MRAM cell for writing in a thermal select or spin torque MRAM. For small node sizes (i.e., minimum feature sizes), approaching 28 nm or lower, the ability of select devices such as diodes or transistors to drive sufficient current demands a relatively large active area. In some cases this large active area may cause the layout of the select device to be larger than a resistive memory element or larger than a minimum spacing between memory elements. In this sense, the select device may become limiting for the cell layout size.

According to an embodiment of the invention small cell sizes may be achieved using a memory cell layout method that decouples a memory-limited cell size assessment from a transistor-limited cell size assessment, and optimizing and combining the two cell size assessments. Similarly, according to an embodiment, small cell sizes may be achieved by optimizing memory-specific parameters with respect to a transistor-limited cell size assessment.

As will be discussed below, using these methods for performing layout for small cell sizes, according to one embodiment of the invention a layout for a sub-10F² MRAM cell may be used, in which the elliptical MTJs are tilted and shifted for each row of cells. In one embodiment of the invention, a sub-10F² MRAM cell may be designed having “criss-cross” patterns of memory elements in rows to achieve a compact cell structure.

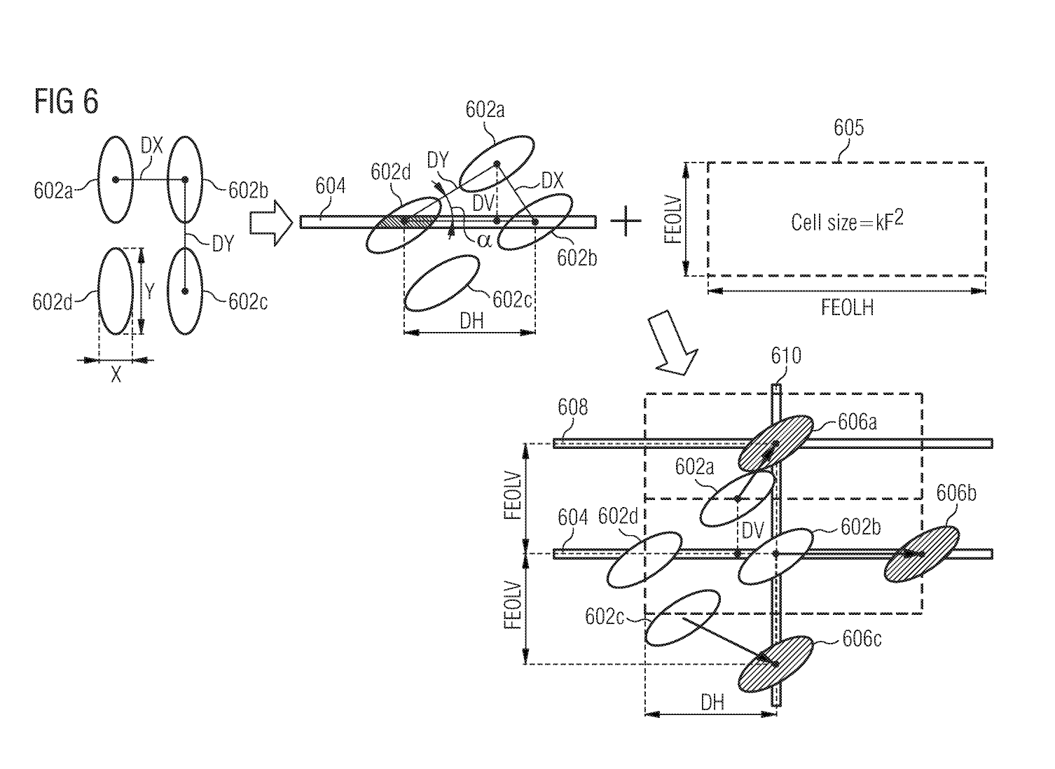

Referring to FIG. 6, an embodiment of a layout method according to the principles of the invention is described. In the embodiment shown in FIG. 6, the memory cell structure that is being laid out is for use with an MRAM device having an elliptical MTJ. In this embodiment, the method determines a layout for MTJs 602a, 602b, 602c, and 602d, each of which has a width “X”, and a height “Y”. A magnetics simulation may be used to determine a minimum separation between the MTJs. In the embodiment shown in FIG. 6, the minimum horizontal distance is shown as “DX”, and the minimum vertical distance is shown as “DY”.

An orientation of the MTJs 602a-602d is rotated by an angle α, so that diagonally opposite MTJs (in this case, MTJs 602b and 602d) are aligned along a bit line 604. When the MTJs are arranged in this manner, the horizontal distance between the diagonally opposite MTJs is labeled “DH”, and the vertical distance from the bit line 604 to the center of one of the MTJs located off of the bit line 604 (e.g., MTJs 602a and 602c) is labeled “DV”. DH and DV provide a minimum cell size based on memory-specific parameters (in this example embodiment, MRAM-specific parameters). DV, DH, and a may be determined according to the following:

α=tan⁻¹(DX/DY) (Eq. 1)

DV=DY sin(α) (Eq. 2)

DH=DX/sin(α) (Eq. 3)

Separately, a minimum cell size based on the front-end-of-line (FEOL) layout of the transistor (or other select device) may be determined. The FEOL transistor size 605 is determined according to electrical parameters or characteristics, such as the required drive currents for switching, required Rₒₙ vs. R_{off} ratios of the select device, endurance and reliability requirements of the select device, the resistance of the memory element, semiconductor design rules, and process assumptions. Based on these parameters, a minimum cell size of kF², where F is the minimum feature size, is determined. The FEOL transistor size provides a minimum vertical size, labeled “FEOLV”, and a minimum horizontal size, labeled “FEOLH”.

The memory-specific minimum sizes may then be compared to the FEOL transistor minimum sizes to determine a minimum cell size for the layout of an integrated circuit memory device. In this embodiment, if DH<FEOLH and DV<FEOLV, then the cell size is limited by the transistor size, and the minimum cell size will be kF², the size of the FEOL layout of the transistor, based on electrical characteristics. If DH>FEOLH or DV>FEOLV, then the cell size is limited by the memory-specific parameters, and after adjustment, the minimum cell size will be larger than kF².

In the example shown in FIG. 6, DH<FEOLH and DV<FEOLV, so the size of the cell is limited by the transistor dimensions. Consequently, the positions of the MTJs are adjusted to conform with the transistor dimensions. In the example shown in FIG. 6, MTJ 602a is moved to a position 606a, MTJ 602b is moved to a position 606b, and MTJ 602c is moved to a position 606c, such that the distance from the bit line 604 to MTJs located above or below the bit line 604 is equal to FEOLV, and the distance between the MTJs located on the bit line 604 is equal to FEOLH. The positions of the MTJs in the layout also may be adjusted to conform to other aspects of the electrical or memory-specific characteristics of the layout, such as positioning MTJs at the intersections of a bit line, such as bit line 604 or bit line 608, and a word line, such as word line 610.

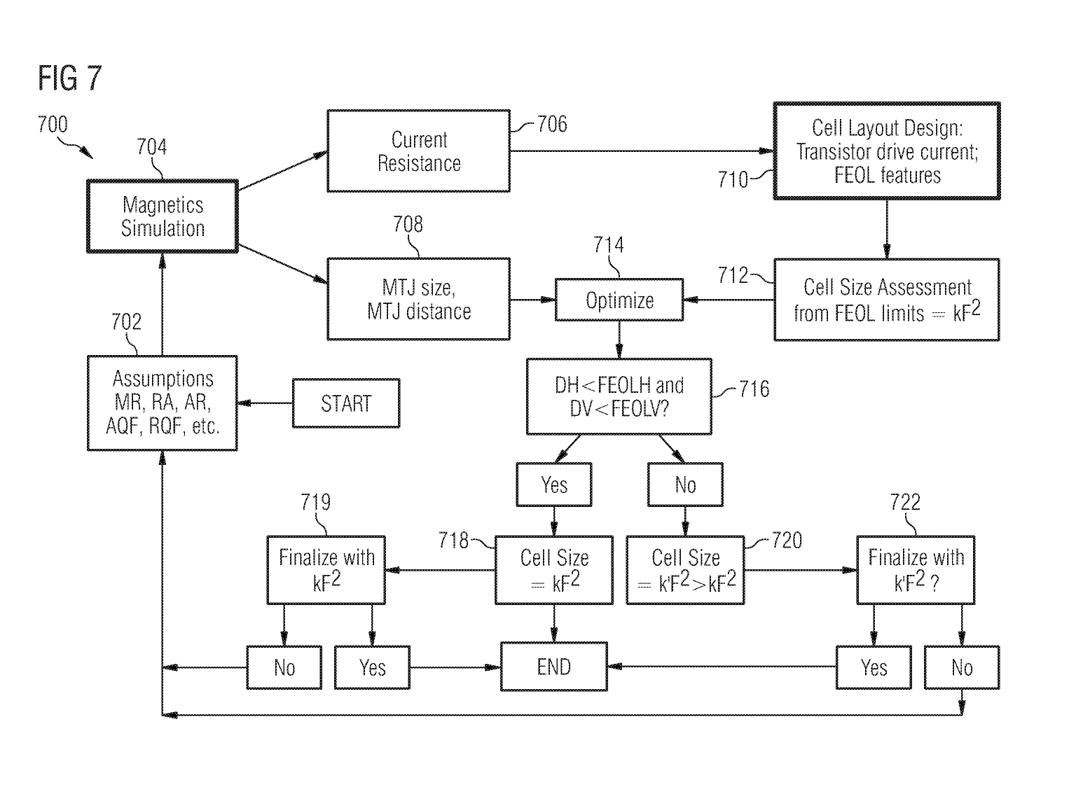

FIG. 7 shows a block diagram of a layout method 700 for MRAM in accordance with an embodiment of the invention. In 702, assumptions regarding the characteristics of the MRAM device are compiled. These assumptions may include parameters such as magneto-resistance ratio (MR), breakdown voltage (VBD), RA (a measure of resistance times area, useful for characterizing the resistance of an MTJ), voltage dependence of MR signal, spin injection efficiency (for a spin injection MRAM), heating efficiency (e.g., for a thermal select MRAM), aspect ratio (AR) of the MTJs, required data retention stability, intrinsic and perpendicular magnetic anisotropies, array quality factor (AQF—the mean switching field of an array of non-interacting MTJs, useful as a measure of switching uniformity), read quality factor (RQF—a measure of relative resistance fluctuations with respect to the signal separation of the low and high resistance states), cell distance, material parameters, and/or other parameters useful in characterizing an MRAM device.

In 704, these assumptions on the characteristics of the MRAM device are used in a magnetics simulation, that determines features of the MRAM device based on the assumptions. The features that are determined include electrical features 706, such as current for read and write operations and resistance, and MRAM-specific features 708, such as MTJ size and MTJ distance and layer thickness, as well as other MRAM-specific parameters, such as AR, or other parameters discussed above.

In 710, the electrical features 706 are used in a cell layout design process to determine a transistor drive current, and the front-end-of-line (FEOL) features and geometry of a FEOL component such as a transistor (or multiple transistors, in the case of cells driven by more than one transistor) that can provide the drive current and/or other electrical characteristics, such as Rₒₙ and R_{off} ratios of the FEOL component (i.e., the select device). In some embodiments, other FEOL components, such as diodes or other active components used for selection or switching in memory devices could be used in the layout process.

Based on the FEOL features, FEOL limits, and geometries, in 712, a cell size assessment is used to determine the area of the cell as kF², where F is the minimum feature size for the technology that is being used. In some embodiments, this process also provides the FEOLH and FEOLV parameters, as described above with reference to FIG. 6.

In 714, an optimization process optimizes the cell size, based on the cell size assessment and on the MRAM-specific features 708, including the MTJ size and distance. In some embodiments, this optimization process may apply one or more tilt angles to the array of MTJs, to align with the FEOL geometry of the transistor. This process may yield the DH and DV and a parameters, discussed above with reference to FIG. 6.

In 716, DH is compared to FEOLH, and DV is compared to FEOLV. In 718, if DH<FEOLH and DV<FEOLV, then the cell size is limited by the transistor size, and the final cell size will be kF². Otherwise, in 720, the cell size is limited by the MRAM characteristics, and the cell size is k′F², which is greater than kF².

In 719, if the cell size is kF², a determination is made of whether to finalize the cell size as kF². It may be possible to iteratively alter the assumptions, to change the electrical requirements, and therefore change the cell size. For example, MTJs that are close enough to interfere with each other may be hardened to prevent such interference and improve data retention, thereby reducing the acceptable distance between MTJs. However, such hardening may also increase the required switching current, thereby increasing the size of the FEOL component, such as the transistor or other select device. Therefore, by increasing the spacing between MTJs, the hardening may be reduced, and the size of the transistor may be reduced. There may be other instances where, for example, the FEOL limiting cell size can be enlarged, resulting, for example, in a larger current drivability or better Rₒₙ/R_{off} ratio. This may, in turn, enable a denser spacing of the memory elements.

Thus, in 719, if it is determined that there is the possibility of improving the layout by altering the assumptions, then the system may alter the parameters, and repeat the method. Otherwise, if it is determined that the layout is acceptable (e.g., the cell size is small enough to meet a density requirement), or that the layout will not be improved by further alteration of the parameters and repetition of the method, then the cell size may be finalized as kF².

In 722, if the cell size is k′F², a determination is made whether to finalize the cell size as k′F². This determination may be made, for example, based on whether k′F² is smaller than a desired cell size, or smaller than a cell size needed to achieve a desired density or capacity for a memory device. If the cell size is finalized as k′F², then the process is complete. Otherwise, the assumptions may be altered, hopefully to achieve a more suitable cell size, and the process may be iteratively repeated.

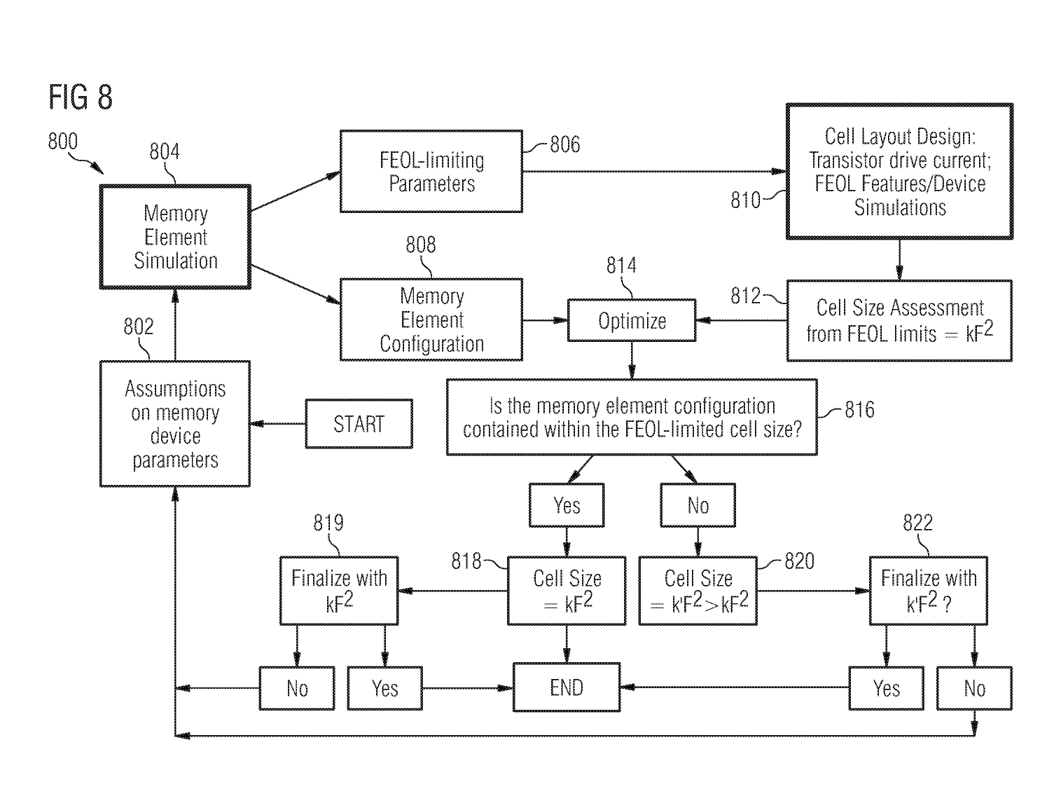

FIG. 8 shows a block diagram of a generalized method for cell size determination and layout 800 in accordance with an embodiment of the invention. The method 800 shown in FIG. 8 is similar to that shown in FIG. 7, but is not specific to the layout of MRAM devices. For example, the method 800 may also be used for other memory types, including PCRAM, CBRAM, and others.

In 802, assumptions regarding the characteristics of the memory device are compiled. For example, for an MRAM device, these assumptions may include the parameters described above with reference to FIG. 7. For a CBRAM device, the assumptions may include parameters such as the on current, off current, on and off voltages, compliance, cell-to-cell interaction parameters, material parameters, programming speed, pulse shape, and others. For PCRAM, the assumptions may include parameters such as heating current, resistance, thermal confinement, cell-to-cell distance, material parameters, and others. Generally, the assumptions will include numerous parameters which may be specific to the memory technology that is being used.

In 804, these assumptions on the characteristics of the memory device are used in a memory element simulation, that determines features of the memory device based on the assumptions. The features that are determined include FEOL-limiting parameters 806, such as electrical characteristics that may affect the FEOL features of the transistor or other FEOL components or elements of the memory cell, and memory element configuration features 808, which include layout and geometry information on the memory cell, such as the size of memory cells, their geometry, and the minimum distances that are required between memory cells to avoid cell-to-cell interference.

In 810, the FEOL-limiting parameters 806 are used in an FEOL-based cell layout design process to determine a transistor drive current, Rₒₙ/R_{off} ratios, reliability, overdrive requirements, and the FEOL features and geometry of transistor(s) or other FEOL components that can provide the drive current and/or other electrical characteristics. In some embodiments, these features may be based on a device simulation that uses the FEOL-limiting parameters as input to the simulation.

Based on these features, including the FEOL features and limits, in 812, a FEOL-based cell size assessment is used to determine the area of the cell as kF², where F is the minimum feature size for the technology that is being used.

In 814, an optimization process optimizes the cell size, based on the cell size assessment and on the memory element configuration features 808. In some embodiments, this optimization process may apply one or more tilt angles to the array of memory elements, to align with the FEOL features.

In 816, it is determined whether the memory element configuration produced by the optimization process of 814 is contained within the FEOL-limited cell size. In 818, if the memory element configuration is contained within the FEOL-limited cell size, then the cell size will be kF². Otherwise, in 820, the cell size is limited by the memory element configuration, and the cell size is k′F², which may be greater than kF².

In 819, if the cell size was kF², a determination will be made of whether to finalize the cell size as kF². As discussed above with reference to FIG. 7, it may be possible to iteratively alter the assumptions, to change the electrical requirements, and therefore change the cell size. If it is determined that there is the possibility of improving the layout by altering the assumptions, then the system may alter the parameters, and repeat the process. Otherwise, if it is determined that the layout is acceptable (e.g., the cell size is small enough to meet a density requirement), or that the layout will not be improved by further alteration of the parameters and repetition of the method, then the cell size may be finalized as kF².

In 822, if the cell size was determined to be k′F², a determination is made whether to finalize the cell size as k′F². This determination may be made, for example, based on whether k′F² is smaller than a desired cell size, or smaller than a cell size needed to achieve a desired density or capacity for a memory device, or on whether further improvements to the layout may be achieved by further adjustment of the assumptions and repetition of the method. If the cell size is finalized as k′F², then the method is complete. Otherwise, the assumptions may be altered, hopefully to achieve a more suitable cell size, and the method may be iteratively repeated.

As can be seen, in a general layout method according to an embodiment of the invention, the memory-specific design characteristics, such as the memory element simulation 804 and the memory element configuration features 808 are decoupled from the electrical design characteristics, such as the FEOL-limiting parameters 806, the FEOL-based cell layout design process 810 and the FEOL-based cell size assessment in 812. While there may be input from the memory-specific characteristics that affect the FEOL characteristics, such as the resistance and current demands of the memory element, the electrical characteristics and the memory-specific characteristics lead to two sets of constraints on the cell size that are combined according to some embodiments of the invention.

In some embodiments, separate simulations are used. For example, as shown in FIG. 8, a memory element simulation (in 804) is used to handle memory cell specific parameters, and to determine spacing between memory elements. This simulation may be specific to the type of memory being used, and may handle different sets of parameters depending on the type of memory. As discussed above, for MRAM, the parameters may include MR, VBD, RA, RQF, AQF, cell distance, material parameters, and others. For CBRAM, the parameters may include on and off currents, on and off voltages, compliance parameters, cell-to-cell interaction parameters, and others. For PCRAM, the parameters may include heating current, resistance, thermal confinement, cell-to-cell distance, and others.

A FEOL feature and device simulation may be used (e.g., in 810) to handle electrical design characteristics. This simulation may cover select device performance for a given layout and a set of start values for operation points. The simulation may, for example, cover FEOL features such as transistor geometry and/or transistor operation points for switching the memory element based on drive currents for switching, heating or programming, reliability aspects arising due to high current and switching voltages, or on other operation parameters of a memory element, as well as on design rules and process assumptions. Back-end-of-line (BEOL) layout may be done according to design rules and process assumptions.

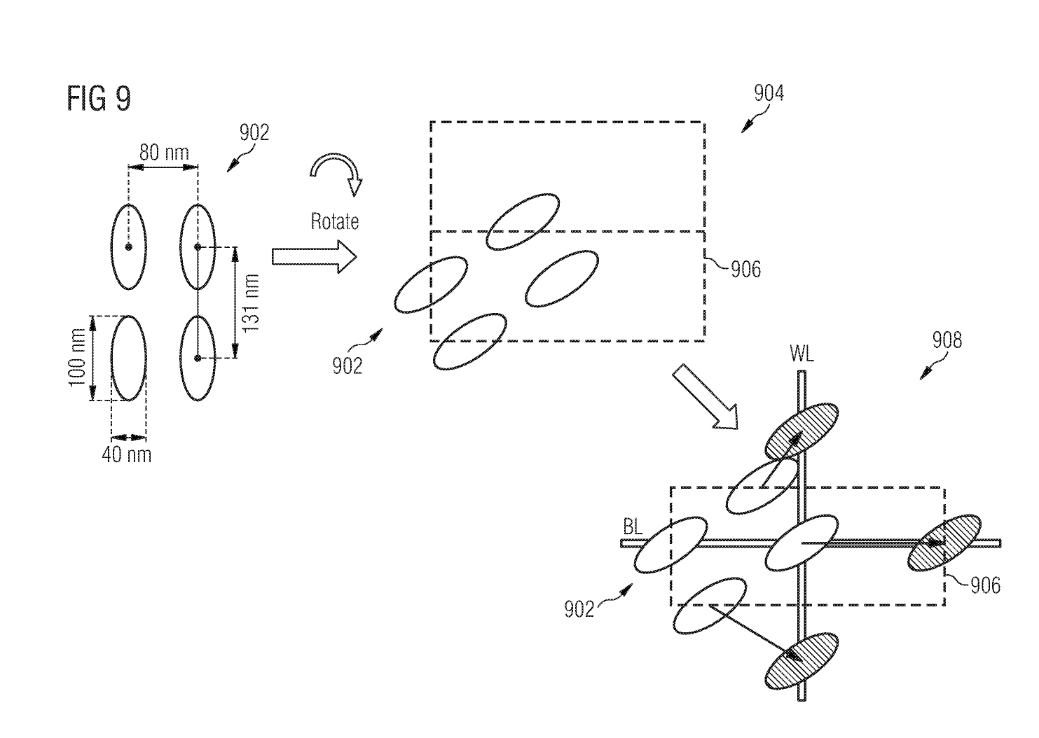

Referring to FIG. 9, an example of a layout process according to an embodiment of the invention, as applied to an example cell design for an MRAM device at a 65 nm node (i.e. minimum feature) size is described. Memory element layout 902 is produced by a memory element simulation. In the example shown in FIG. 9, the memory element layout 902 shows that the MTJs are each 100 nm in height, 40 nm in width, and have a minimum spacing of 80 nm in the horizontal direction, and 131 nm in the vertical direction.

Next, as shown in view 904, the memory element layout 902 is rotated to match an orientation of a FEOL transistor configuration 906 produced as a result of the electrical characteristics of the memory cell. The FEOL transistor configuration 906 also provides a minimum cell size based on the electrical characteristics. In this example, the FEOL transistor configuration 906 uses a double FinFET to achieve a cell size of 10F² while providing sufficient current to write to an MTJ.

Next, as shown in view 908, the minimum size of the memory element layout 902 is compared with the minimum size of the FEOL transistor configuration 906, and the positions of the memory elements in the memory element layout 902 are shifted to fit the transistor configuration 906.

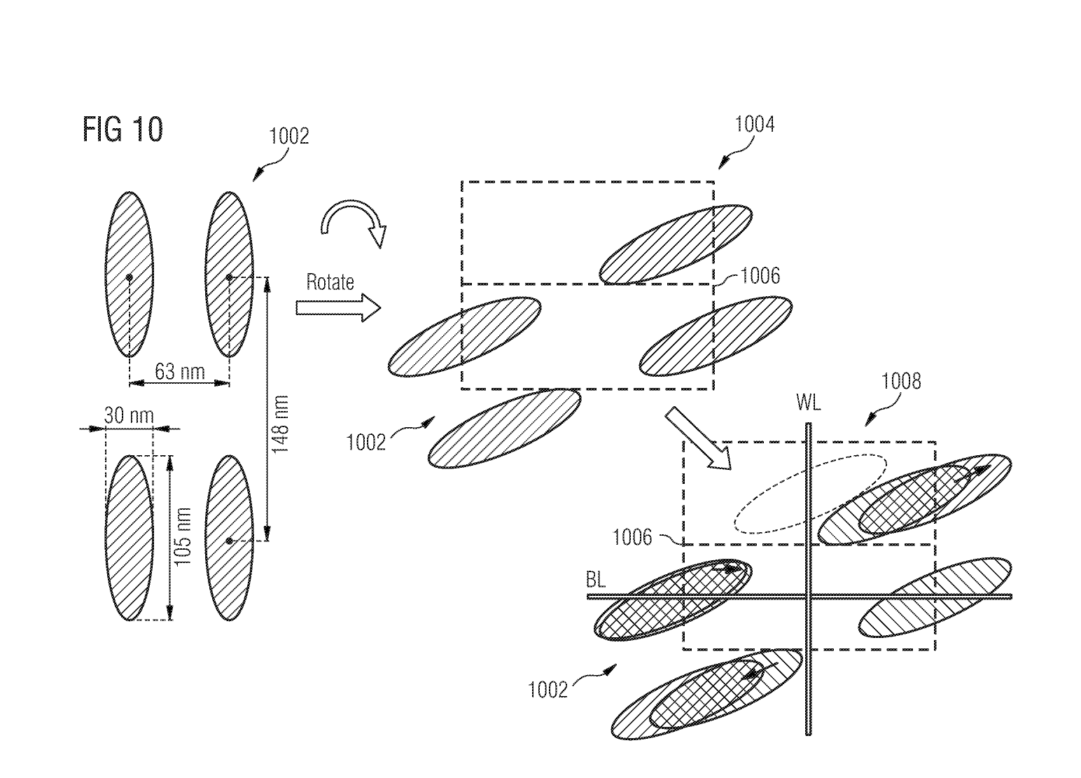

FIG. 10 shows a further example in accordance with an embodiment of the invention, for a 32 nm node size. As shown in this example, a memory element layout 1002, produced by a memory element simulation, has MTJs that are each 105 nm in height, 30 nm in width, and have a minimum spacing of 63 nm in the horizontal direction, and 148 nm in the vertical direction. These dimensions may be the result of several iterations of adjustment of parameters, such as the aspect ratio of the MTJs, according to a method such as those described above.

Next, as shown in view 1004, the memory element layout is rotated to fit an orientation of a FEOL transistor configuration 1006. In accordance with an embodiment of the invention, the FEOL transistor configuration 1006 may be produced by an FEOL features/device simulation that determines the FEOL layout and electrical characteristics of a cell based on various electrical parameters. In this example, the FEOL transistor configuration 1006 uses a double FinFET to achieve a cell size of 10F2 while providing sufficient current to drive an MRAM cell. Because the node size (i.e., F) is only 32 nm in this example, a 10F² cell is considerably smaller in this example than in the example described with reference to FIG. 9, above.

In view 1008, the minimum size of the memory element layout 1002 is compared with the minimum size of the FEOL transistor configuration 1006. Based on this comparison, the positions of the MTJs in the memory element layout 1002 are shifted to fit the transistor configuration 1006.

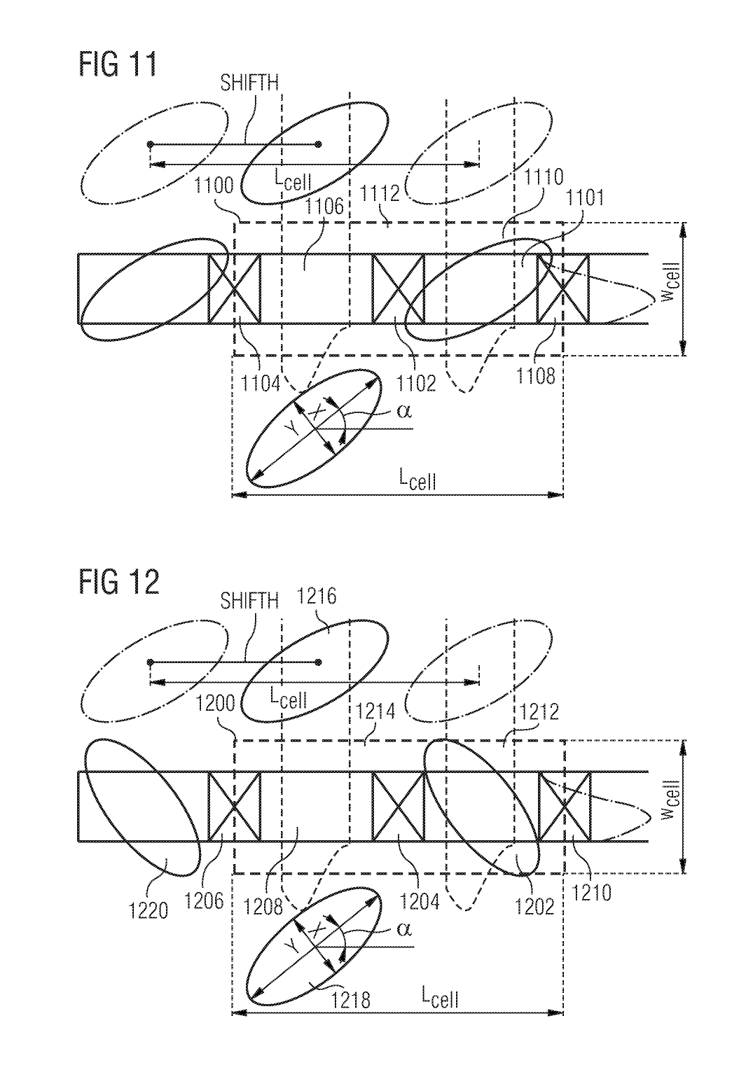

Referring now to FIG. 11, a sample layout of an integrated circuit MRAM device derived in accordance with an embodiment of the invention is described. As in the prior two examples, the MRAM cell layout shown in FIG. 11 uses a double FinFET to achieve a FEOL transistor size of 10F², with a length “L_{cell}” and a width “W_{cell}”.

The MRAM cell 1100 includes an MTJ 1101, and a shared source/drain region 1102 that is shared by the two FinFET transistors that provide current to write to the MTJ 1101. The first of these transistors also includes a first source/drain region 1104 (which is also shared with an adjacent cell), and a first gate 1106 (which may also be a word line for the cell). The second of the FinFETs also includes a second source/drain region 1108 (also shared with an adjacent cell), and a second gate 1110 (which may also be a word line). The shared source/drain region 1102 is electrically connected (directly or indirectly) to the MTJ 1101. An isolation region 1112 separates the cell from adjacent rows of cells.

As can be seen, each MTJ, such as MTJ 1101, has an elliptical shape having a major axis of length “X” and a minor axis of length “Y”. Thus, the aspect ratio of the MTJs (including MTJ 1101) can be expressed X/Y. In one embodiment, an example range for the aspect ratio of the MTJs may be 0.2 to 5. The MTJs are tilted at a tilt angle of α (0°<α<90°). This tilt angle permits a relatively compact arrangement of the MTJs to be used, while still maintaining minimum distances between the MTJs to prevent cell-to-cell interference. Additionally, in order to match the layout of the MTJs to the cell spacing, the locations of cells may be shifted. In the example shown in FIG. 11, a horizontal shift labeled “SHIFTH” may be applied to MTJs in alternating rows, where 0<SHIFTH<L_{cell}.

It will, of course, be understood that the integrated circuit MRAM device layout shown in FIG. 11 is just one example of a layout in accordance with an embodiment of the invention. Application of the methods described above can produce other layouts, depending on the memory-specific parameters and the electrical parameters. For example, layouts in which only a single transistor per cell is used, instead of two FinFETs may be produced. Additionally, the aspect ratios, sizes, and distances of the MTJs may vary, as well as the tilt angle and shift distances. For example, in some embodiments, rows of MTJs may also be shifted in a vertical direction.

In FIG. 12, an additional example of a layout for an integrated circuit MRAM device in accordance with an embodiment of the invention is shown. In this example, the layout method is able to apply different shift angles to different “rows” of MTJs, producing cells in a “criss-cross” pattern. As in the previous example, a double FinFET configuration is used to provide the current for switching the MTJs, to achieve a FEOL cell size of 10F² or smaller, with a length of L_{cell}, and a width of W_{cell}.

As in the previous example, an MRAM cell 1200 includes an MTJ 1202, and a shared source/drain region 1204 that is shared by two FinFET transistors that provide current to write the MTJ 1202. The first of these transistors also includes a first source/drain region 1206 (which is also shared with an adjacent cell), and a first gate 1208 (which may also be a word line for the cell). The second FinFET includes a second source/drain region 1210 (also shared with an adjacent cell), and a second gate 1212 (which may also be a word line). The shared source/drain region 1204 is electrically connected (directly or indirectly) to the MTJ 1202. An isolation region 1214 separates the cell from adjacent rows of cells.

Each of the MTJs, such as MTJ 1202, has an elliptical shape having a major axis of length “X” and a minor axis of length “Y”, and an aspect ratio (Y/X) in the range (in this example) of 0.2 to 5. In accordance with an embodiment of the invention, alternating rows of MTJs may have differing tilt angles, forming a “criss-cross” pattern of MTJs to achieve a compact arrangement while maintaining minimum distances to avoid cell-to-cell interference. In the example shown in FIG. 12, the MTJs 1216 and 1218 have a tilt angle of α (0°<α<90°), while the MTJs 1202 and 1220 have a tilt angle of α (90°<α<180°). Additionally, as in the previous example, the locations of cells may be shifted to match the FEOL transistor spacing. In the example shown in FIG. 12, a horizontal shift labeled “SHIFTH” may be applied to MTJs, including MTJ 1216, where 0<SHIFTH<L_{cell}.

It will be understood that, as with previous examples, many alterations could be made to the integrated circuit MRAM device layout shown in FIG. 12. For example, layouts in accordance with embodiments of the invention may use only a single transistor per cell, use different aspect ratios, sizes, and distances of the MTJs or other memory elements, and/or have different tilt angles and shift distances and directions.

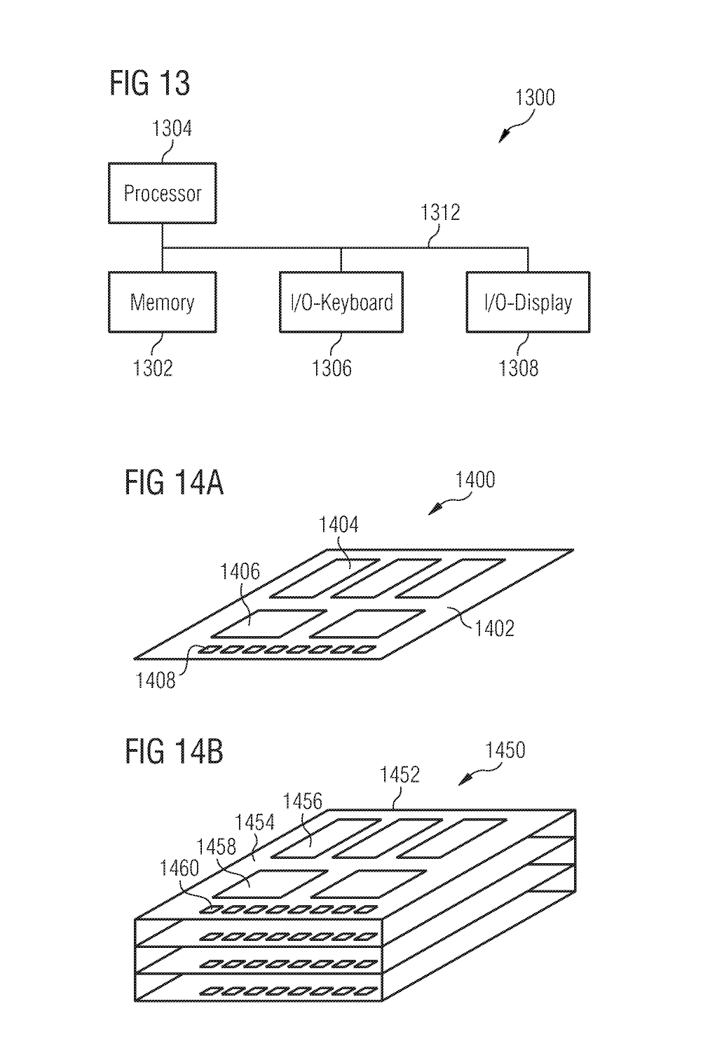

In some embodiments, the methods for determining memory cell layouts described above, for example, with reference to FIGS. 6, 7, 8, 9, and 10, may be carried out on a computer programmed to determine a memory cell layout. An example of such a computer is shown in FIG. 13. The computer 1300 includes a memory 1302, a processor 1304, and one or more input/output devices, such as a keyboard 1306, and display 1308. The memory 1302, processor 1304, keyboard 1306, and display 1308 are interconnected by a bus 1312. It will be understood that many alternative system designs may be used, which may include different input/output devices, multiple processors, alternative bus configurations, and many other configurations. For example, a standard “PC compatible” computer, commercially available from many sources may be used.

The processor 1304 is programmed using instructions stored in the memory 1302 to carry out a memory cell layout process, in accordance with an embodiment of the invention. The processor 1304 may be any processor capable of executing programmed instructions, including processors using a CISC architecture, a RISC architecture, or any other processor architecture.

Memory cells laid out in accordance with an embodiment of the invention may be used in memory devices that contain large numbers of such cells. These cells may, for example, be organized into an array of memory cells having numerous rows and columns of cells, each of which stores more than one bit of information. Memory devices of this sort may be used in a variety of applications or systems. As shown in FIGS. 14A and 14B, in some embodiments, memory devices such as those described herein may be used in modules. In FIG. 14A, a memory module 1400 is shown, on which one or more memory devices 1404 are arranged on a substrate 1402. Each memory device 1404 may include numerous memory cells in accordance with an embodiment of the invention. The memory module 1400 may also include one or more electronic devices 1406, which may include memory, processing circuitry, control circuitry, addressing circuitry, bus interconnection circuitry, or other circuitry or electronic devices that may be combined on a module with a memory device 1404. Additionally, the memory module 1400 includes multiple electrical connections 1408, which may be used to connect the memory module 1400 to other electronic components, including other modules. For example, the memory module 1400 may be plugged into a larger circuit board, including PC main boards, video adapters, cell phone circuit boards or portable video or audio players, among others.

As shown in FIG. 14B, in some embodiments, these modules may be stackable, to form a stack 1450. For example, a stackable memory module 1452 may include one or more memory devices 1456, arranged on a stackable substrate 1454. Each of the memory devices 1456 includes memory cells that employ memory elements in accordance with an embodiment of the invention. The stackable memory module 1452 also may include one or more electronic devices 1458, which may include memory, processing circuitry, control circuitry, addressing circuitry, bus interconnection circuitry, or other circuitry or electronic devices that may be combined on a module with a memory device 1456. Electrical connections 1460 are used to connect the stackable memory module 1452 with other modules in the stack 1450, or with other electronic devices. Other modules in the stack 1450 may include additional stackable memory modules, similar to the stackable memory module 1452 described above, or other types of stackable modules, such as stackable processing modules, control modules, communication modules, or other modules containing electronic components.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of producing an integrated circuit, the method comprising:
determining a layout for a plurality of memory elements based on memory-specific parameters;
determining a layout for a front-end-of-line (FEOL) component of the integrated circuit based on electrical parameters;
combining the layouts for the plurality of memory elements and the FEOL component to produce a combined layout for a memory cell; and
fabricating an integrated circuit based upon the combined layout.

2. The method of claim 1, wherein determining the layout for the plurality of memory elements comprises using a memory element simulation.

3. The method of claim 1, wherein determining the layout for the plurality of memory elements comprises determining a minimum distance between memory elements to avoid cell-to-cell interference.

4. The method of claim 1, wherein determining the layout for the FEOL component comprises determining a minimum size for the FEOL component.

5. The method of claim 1, wherein determining the layout for the FEOL component comprises determining a length and a width of the FEOL component.

6. The method of claim 1, wherein determining the layout for the FEOL component comprises determining a layout for a transistor.

7. The method of claim 1, wherein combining the layouts comprises applying a first tilt angle to the layout for the plurality of memory elements.

8. The method of claim 7, wherein applying the first tilt angle comprises applying a first tilt angle between 0 and 90° relative to the layout for the FEOL component.

9. The method of claim 7, wherein combining the layouts further comprises applying a second tilt angle to the layout for the plurality of memory elements, such that the first tilt angle and the second tilt angle apply to alternating rows of memory elements to provide a criss-cross pattern of memory elements.

10. The method of claim 1, wherein combining the layouts comprises shifting a position of at least one memory element in the plurality of memory elements to correspond to the layout of the FEOL component.

11. The method of claim 10, wherein shifting a position of the at least one memory element comprises shifting the position of at least one memory element in a vertical direction.

12. The method of claim 11, wherein shifting the position of the at least one memory element comprises shifting the position of the at least one memory element in a horizontal direction.

13. The method of claim 1, wherein combining the layouts comprises comparing a dimension of the layout for the plurality of memory elements with a dimension of the layout for the FEOL component.

14. The method of claim 1, further comprising iteratively adjusting the layout for the plurality of memory elements and/or the layout for the FEOL component, and combining the layouts to form a combined layout until a final layout is determined.

15. The method of claim 14, wherein the final layout is determined when the combined layout has a memory cell size below a predetermined size.

16. The method of claim 1, wherein determining the layout for the plurality of memory elements comprises determining the layout for the plurality of memory elements of an MRAM device, a PCRAM device, a CBRAM device, a carbon memory device, or a transition metal oxide memory device.

17. An integrated circuit comprising:
a plurality of memory elements, the plurality of memory elements having a layout based on memory-specific parameters; and
a plurality of front-end-of-line (FEOL) components, the FEOL components having a layout based on electrical characteristics,
wherein the plurality of memory elements and the plurality of FEOL components are combined to form a plurality of memory cells, the memory cells having a layout based on a combination of the layout of the plurality of memory elements and the layout of the plurality of FEOL components.

18. The integrated circuit of claim 17, wherein the plurality of memory elements are arranged to have a first tilt angle with respect to the plurality of FEOL components.

19. The integrated circuit of claim 18, wherein the tilt angle is greater than 0° and less than 90°.

20. The integrated circuit of claim 18, wherein the memory elements have an elliptical shape.

21. The integrated circuit of claim 20, wherein the memory elements have an aspect ratio between 0.2 and 5.

22. The integrated circuit of claim 17, wherein the plurality of memory elements are arranged so that a first row of memory elements has a first tilt angle with respect to the plurality of FEOL components, and a second row of memory elements has a second tilt angle with respect to the plurality of FEOL components.

23. The integrated circuit of claim 22, wherein the first tilt angle is between 0° and 90°, and the second tilt angle is between 90° and 180°.

24. The integrated circuit of claim 22, wherein the first row of memory elements and the second row of memory elements are adjacent, forming a criss-cross pattern of memory elements.

25. The integrated circuit of claim 24, wherein the memory elements have an elliptical shape.

26. The integrated circuit of claim 25, wherein the memory elements have an aspect ratio between 0.2 and 5.

27. The integrated circuit of claim 17, wherein the plurality of FEOL components comprise transistors.

28. The integrated circuit of claim 27, wherein the transistors comprise FinFETs.

29. The integrated circuit of claim 28, wherein each memory cell comprises at least two FinFETs.

30. The integrated circuit of claim 17, wherein the plurality of memory elements comprise MRAM, PCRAM, CBRAM, transition metal oxide, or carbon memory elements.

31. A method of designing a memory cell layout, the method comprising:
determining a memory-specific minimum cell size based on memory-specific parameters;
determining a front-end-of-line (FEOL) component minimum size based on electrical parameters;
comparing the memory-specific minimum cell size with the FEOL component minimum size; and
adjusting the memory cell layout based on the results of comparing.

32. The method of claim 31, wherein determining the memory-specific minimum cell size comprises using a memory element simulation.

33. The method of claim 31, wherein determining the FEOL component minimum size comprises using an electrical simulation.

34. The method of claim 31, wherein determining the FEOL component minimum size comprises determining a layout for a transistor.

35. The method of claim 31, wherein determining the memory-specific minimum cell size comprises applying a tilt angle to a layout of a plurality of memory elements.

36. The method of claim 31, wherein adjusting the memory cell layout comprises shifting a position of at least one memory element to correspond to a layout of a FEOL component.

37. The method of claim 31, wherein comparing the memory-specific minimum cell size with the FEOL component minimum size comprises comparing a dimension of a layout of a plurality of memory elements with a dimension of a layout of a FEOL component.

38. The method of claim 31, wherein determining the memory-specific minimum cell size comprises determining a minimum cell size for an MRAM cell based on parameters comprising one or more of magneto-resistance ratio, breakdown voltage, RA, voltage dependence of MR signal, spin injection efficiency, heating efficiency, aspect ratio of a memory element, required data retention stability, intrinsic and perpendicular magnetic anisotropies, read quality factor, array quality factor, cell distance, and a material parameter.

39. The method of claim 31, wherein determining the memory-specific minimum cell size comprises determining a minimum cell size for a CBRAM device based on parameters comprising one or more of on current, off current, on voltage, off voltage, compliance, programming speed, pulse shape, a cell-to-cell interaction parameter, and a material parameter.

40. The method of claim 31, wherein determining the memory-specific minimum cell size comprises determining a minimum cell size for a PCRAM device based on parameters comprising one or more of heating current, resistance, thermal confinement, programming speed, pulse shape, cell-to-cell distance, and a material parameter.

41. The method of claim 31, wherein determining the front-end-of-line (FEOL) component minimum size comprises determining a minimum FEOL size for a transistor based on parameters comprising one or more of drive current for switching a memory element, resistance of a memory element, Rₒₙ/R_{off} ratios, reliability, overdrive requirements, a semiconductor design rule, and a semiconductor process assumption.

42. A system for designing a memory cell layout, the system comprising:
a memory and a processor, the memory comprising a plurality of programmed instructions that when executed by the processor cause the processor to:
determine a memory-specific minimum cell size based on memory-specific parameters;
determine a front-end-of-line (FEOL) component minimum size based on electrical parameters;
compare the memory-specific minimum cell size with the FEOL component minimum size;
adjust the memory cell layout based on the results of comparing; and
output the memory cell layout.

43. The system of claim 42, wherein the programmed instructions cause the processor to determine the memory-specific minimum cell size using a memory element simulation.

44. The system of claim 42, wherein the programmed instructions cause the processor to determine the FEOL component minimum size using an electrical simulation.

45. The system of claim 42, wherein the programmed instructions cause the processor to determine the FEOL component minimum size by determining a layout for a transistor.

46. The system of claim 42, wherein the programmed instructions cause the processor to apply a tilt angle to a layout of a plurality of memory elements to determine the memory-specific minimum cell size.

47. The system of claim 42, wherein the programmed instructions cause the processor to shift a position of at least one memory element to correspond to a layout of an FEOL component to adjust the memory cell layout.

48. The system of claim 42 wherein the programmed instructions cause the processor to determine a layout for at least one of an MRAM device, a PCRAM device, a CBRAM device, a carbon memory device, and a transition metal oxide memory device.

49. A memory module comprising:
a plurality of integrated circuits electrically interconnected as a memory module, wherein each integrated circuit comprises:
a plurality of memory elements, the plurality of memory elements having a layout based on memory-specific parameters; and
a plurality of front-end-of-line (FEOL) components, the FEOL components having a layout based on electrical characteristics,
wherein the plurality of memory elements and the plurality of FEOL components are combined to form a plurality of memory cells, the memory cells having a layout based on a combination of the layout of the plurality of memory elements and the layout of the plurality of FEOL components.

50. The memory module of claim 49, wherein, for each integrated circuit, the plurality of memory elements are arranged to have a first tilt angle with respect to the plurality of FEOL components.

51. The memory module of claim 49, wherein, for each integrated circuit, the plurality of memory elements are arranged so that a first row of memory elements has a first tilt angle with respect to the plurality of FEOL components, and a second row of memory elements has a second tilt angle with respect to the plurality of FEOL components.

52. The memory module of claim 51, wherein, for each integrated circuit, the first row of memory elements and the second row of memory elements are adjacent, forming a criss-cross pattern of memory elements.

53. The memory module of claim 49, wherein, for each integrated circuit, the plurality of FEOL components comprise transistors.

54. The memory module of claim 53, wherein the transistors comprise FinFETs.

55. The memory module of claim 49, wherein the plurality of memory elements comprise MRAM, PCRAM, CBRAM, carbon memory, or transition metal oxide memory elements.

56. The memory module of claim 49, wherein the memory module is stackable.
